(19) United States
(12) Patent Application Publication
(10) Pub. No.: US 2020/0056287 A1
(43) Pub. Date: Feb. 20, 2020

(54) Film-Forming Method and Film-Forming Apparatus

(71) Applicant: TOKYO ELECTRON LIMITED, Tokyo (JP)

(72) Inventors: Tsuyoshi TAKAHASHI, Nirasaki City (JP); Kazuyoshi YAMAZAKI, Nirasaki City (JP); Hideo NAKAMURA, Nirasaki City (JP); Yoshikazu IDENO, Nirasaki City (JP)

(21) Appl. No.: 16/538,086

(22) Filed: Aug. 12, 2019

(30) Foreign Application Priority Data
Aug. 17, 2018 (JP) 2018-153702

(51) Int. Cl. C23C 16/455; C23C 16/34

(52) U.S. Cl. CPC C23C 16/45527; C23C 16/45553; C23C 16/34

(57) ABSTRACT

A film-forming method for forming a metal nitride film on a substrate includes: forming the metal nitride film on the substrate by repeating a cycle a predetermined number of times, the cycle including: a first process of supplying a metal-containing gas into a process container configured to accommodate the substrate therein; a second process of supplying a purge gas into the process container; a third process of supplying a nitrogen-containing gas into the process container; and a fourth process of supplying the purge gas into the process container, wherein the fourth process includes: a first step of supplying a first purge gas having a first flow rate equal to or larger than a flow rate of the metal-containing gas of the first process; and a second step of supplying the first purge gas having a second flow rate smaller than the first flow rate.

### CROSS-REFERENCE TO RELATED APPLICATION

This application is based upon and claims the benefit of priority from Japanese Patent Application No. 2018-153702, filed on Aug. 17, 2018, the entire contents of which are incorporated herein by reference.

### TECHNICAL FIELD

The present disclosure relates to a film-forming method and a film-forming apparatus.

### BACKGROUND

There is known a technique for forming a TiN film on a substrate by constantly supplying N₂ gas as a purge gas into process container and alternately and intermittently supplying TiCl₄ gas and NH₃ gas (see, for example, Patent Document 1).

### RELATED ART DOCUMENT

### Patent Documents

Patent Document 1: Japanese Patent Laid-Open Publication No. 2015-78418

### SUMMARY

According to an embodiment of the present disclosure, a film-forming method for forming a metal nitride film on a substrate is provided. The method includes: forming the metal nitride film on the substrate by repeating a cycle a predetermined number of times, the cycle including: a first process of supplying a metal-containing gas into a process container configured to accommodate the substrate therein; a second process of supplying a purge gas into the process container; a third process of supplying a nitrogen-containing gas into the process container; and a fourth process of supplying the purge gas into the process container, wherein the fourth process includes: a first step of supplying a first purge gas having a first flow rate equal to or larger than a flow rate of the metal-containing gas of the first process; and a second step of supplying the first purge gas having a second flow rate smaller than the first flow rate.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic view illustrating an exemplary configuration of a film-forming apparatus.

FIG. 2 is a diagram illustrating an exemplary gas supply sequence in an ALD process.

FIG. 3 is a diagram illustrating another exemplary gas supply sequence in an ALD process.

FIG. 4 is a diagram illustrating still another exemplary gas supply sequence in an ALD process.

FIG. 5 is a diagram illustrating a comparative example of a gas supply sequence in an ALD process.

FIG. 6 is a diagram illustrating another comparative example of a gas supply sequence in an ALD process.

FIG. 7 is a diagram representing a relationship between a film thickness and resistivity of a TiN film.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, non-limiting exemplary embodiments of the present disclosure will be described with reference to the accompanying drawings. In all of the accompanying drawings, the same or corresponding members or components will be denoted by the same or corresponding reference numerals, and redundant explanations will be omitted.

### [Film-Forming Apparatus]

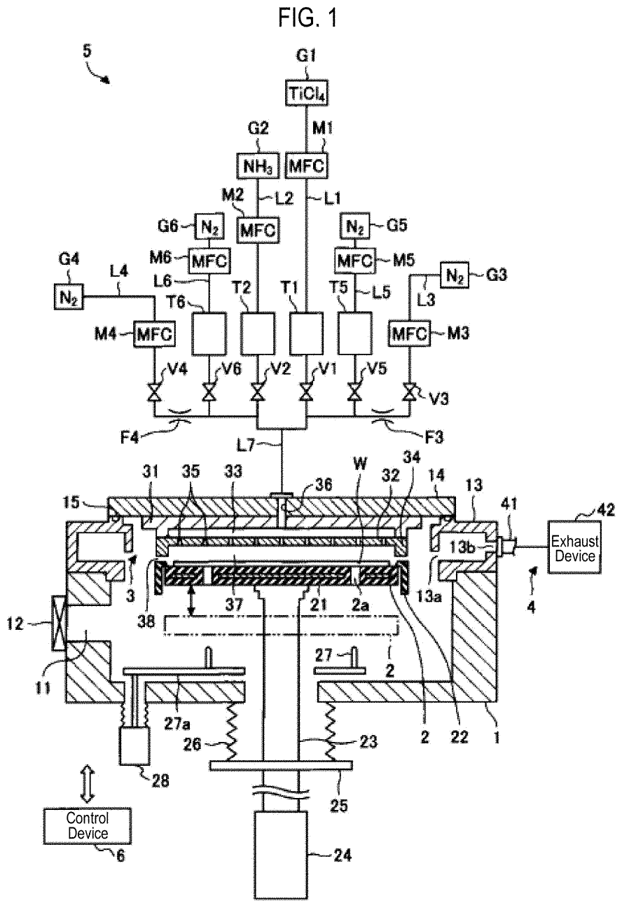

A film-forming apparatus according to an embodiment of the present disclosure will be described. FIG. 1 is a view illustrating an exemplary configuration of a film-forming apparatus.

As illustrated in FIG. 1, the film-forming apparatus includes a process container 1, a substrate mounting table 2, a shower head 3, an exhaust part 4, a processing gas supply mechanism 5, and a control device 6.

The process container 1 is made of a metal such as aluminum and has a substantially cylindrical shape. A loading/unloading port 11 is formed in the side wall of the process container 1 to load/unload a semiconductor wafer W (hereinafter, referred to as a “wafer W”), which is an example of a substrate, therethrough, and the loading/unloading port 11 is configured to be opened and closed by a gate valve 12. An annular exhaust duct 13 having a rectangular cross section is provided on a main body of the process container 1. A slit 13a is formed in the exhaust duct 13 along an inner peripheral surface thereof. In addition, an exhaust port 13b is formed in an outer wall of the exhaust duct 13. On the upper surface of the exhaust duct 13, a ceiling wall 14 is provided so as to close an upper opening of the process container 1. A space between the ceiling wall 14 and the exhaust duct 13 is hermetically sealed with a seal ring 15.

The substrate mounting table 2 horizontally supports the wafer W in the process container 1. The substrate mounting table 2 is formed in a disk shape having a size corresponding to the wafer W, and is supported by a support member 23. The substrate mounting table 2 is made of a ceramic material such as aluminum nitride (AlN) or a metal material such as aluminum or nickel-based alloy, and a heater 21 is embedded in the substrate mounting table 2 in order to heat the wafer W. The heater 21 is fed with power from a heater power supply (not illustrated) and generates heat. Then, by controlling the output of the heater 21 by a temperature signal of a thermocouple (not illustrated) provided in the vicinity of the wafer placement surface of the upper surface of the substrate mounting table 2, the wafer W is controlled to a predetermined temperature.

The substrate mounting table 2 is provided with a cover member 22 including ceramics such as alumina so as to cover an outer peripheral region of the wafer placement surface and a side surface of the substrate mounting table 2.

The support member 23 extends to the lower side of the process container 1 through a hole formed in the bottom wall of the process container 1 from a center of a bottom surface of the mounting table 2, and the lower end of the support member 123 is connected to a lifting mechanism 24. The substrate mounting table 2 is configured to be capable of ascending/descending, via the support member 23 by the lifting mechanism 24, between a processing position illustrated in FIG. 1 and a transport position (indicated by a two-dot chain line below the processing position) where the wafer is capable of being transported. In addition, a flange part 25 is provided on the support member 23 below the process container 1, and a bellows 26, which partitions the atmosphere in the process container 1 from the outside air, is provided between the bottom surface of the process container 1 and the flange part 25 to expand and contract in response to the ascending/descending movement of the substrate mounting table 2.

Three wafer support pins 27 (of which only two are illustrated) are provided in the vicinity of the bottom surface of the process container 1 so as to protrude upward from a lifting plate 27a. The wafer support pins 27 are configured to be capable of ascending/descending via the lifting plate 27a by the lifting mechanism 28 provided below the process container 1, and are inserted into through holes 2a provided in the substrate mounting table 2 located at the transport position so as to be capable of protruding or receding with respect to the upper surface of the substrate mounting table 2. By causing the wafer support pins 27 to ascend or descend in this way, the wafer W is delivered between a wafer transport mechanism (not illustrated) and the substrate mounting table 2.

The shower head 3 supplies a processing gas into the process container 1 in a shower form. The shower head 3 is made of a metal and is provided to face the substrate mounting table 2. The shower head 3 has a diameter, which is substantially equal to that of the substrate mounting table 2. The shower head 3 has a main body part 31 fixed to the ceiling wall 14 of the process container 1 and a shower plate 32 connected to the lower side of the main body part 31. A gas diffusion space 33 is formed between the main body part 31 and the shower plate 32. In the gas diffusion space 33, a gas introduction hole 36 is provided through the center of the main body part 31 and the ceiling wall 14 of the process container 1. An annular protrusion 34 protruding downward is formed at the peripheral edge portion of the shower plate 32, and gas ejection holes 35 are formed in a flat surface inside the annular protrusion 34 of the shower plate 32.

In the state in which the substrate mounting table 2 is located at the processing position, a processing space 37 is formed between the shower plate 32 and the substrate mounting table 2, and the annular protrusion 34 and the upper surface of the cover member 22 of the substrate mounting table 2 come close to each other, thus forming an annular gap 38.

The exhaust part 4 evacuates the inside of the process container 1. The exhaust part 4 includes an exhaust pipe 41 connected to the exhaust port 13b of the exhaust duct 13, and an exhaust mechanism 42 connected to the exhaust pipe 41 and having, for example, a vacuum pump and a pressure control valve. During the processing, the gas in the process container 1 reaches the exhaust duct 13 via the slit 13a, and is exhausted from the exhaust duct 13 through the exhaust pipe 41 by the exhaust mechanism 42 of the exhaust part 4.

The processing gas supply mechanism 5 includes a source gas supply line L1, a nitriding gas supply line L2, a first continuous N₂ gas supply line L3, a second continuous N2 gas supply line L4, a first flash purge line L5, and a second flash purge line L6.

The source gas supply line L1 extends from a source gas supply source G1, which is a supply source of a metal-containing gas (e.g., TiCl₄ gas), and is connected to a merging pipe L7. The merging pipe L7 is connected to the gas introduction hole 36. The source gas supply line L1 is provided with a mass flow controller M1, a buffer tank T1, and an opening/closing valve V1 in this order from the side of the source gas supply source G1. The mass flow controller M1 controls a flow rate of the TiCl₄ gas flowing through the source gas supply line L1. The buffer tank T1 temporarily stores the TiCl₄ gas, and supplies the necessary TiCl₄ gas in a short time. The opening/closing valve V1 switches the supply and stop of TiCl₄ gas during an atomic layer deposition (ALD) process.

The nitriding gas supply line L2 extends from a nitriding gas supply source G2, which is a supply source of a nitrogen-containing gas (e.g., NH₃ gas), and is connected to the merging pipe L7. The nitriding gas supply line L2 is provided with a mass flow controller M2, a buffer tank T2, and an opening/closing valve V2 in this order from the side of the nitriding gas supply source G2. The mass flow controller M2 controls the flow rate of the NH₃ gas flowing through the nitriding gas supply line L2. The buffer tank T2 temporarily stores the NH₃ gas, and supplies the necessary NH₃ gas in a short time. The opening/closing valve V2 switches the supply and stop of the NH₃ gas during the ALD process.

The first continuous N₂ gas supply line L3 extends from an N₂ gas supply source G3, which is the supply source of N₂ gas, and is connected to the source gas supply line L1. Thus, the N₂ gas is supplied to the source gas supply line L1 side through the first continuous N₂ gas supply line L3. The first continuous N₂ gas supply line L3 constantly supplies N₂ gas during film formation through an ALD method, and the N₂ gas functions as a carrier gas of TiCl₄ gas and also functions as a purge gas. The first continuous N₂ gas supply line L3 is provided with a mass flow controller M3, an opening/closing valve V3, and an orifice F3 in this order from the side of N₂ gas supply source G3. The mass flow controller M3 controls the flow rate of the N₂ gas flowing through the first continuous N₂ gas supply line L3. The orifice F3 suppresses a backflow of a relatively large flow rate of gas supplied by the buffer tanks T1 and T5 into the first continuous N₂ gas supply line L3.

The second continuous N₂ gas supply line L4 extends from an N₂ gas supply source G4, which is the supply source of N₂ gas, and is connected to the nitriding gas supply line L2. Thus, the N₂ gas is supplied to the nitriding gas supply line L2 side through the second continuous N₂ gas supply line L4. The second continuous N₂ gas supply line L4 constantly supplies N₂ gas during film formation through an ALD method, and the N₂ gas functions as a carrier gas of NH₃ gas and also functions as a purge gas. The second continuous N₂ gas supply line L4 is provided with a mass flow controller M4, an opening/closing valve V4, and an orifice F4 in this order from the side of N₂ gas supply source G4. The mass flow controller M4 controls the flow rate of the N₂ gas flowing through the second continuous N₂ gas supply line L4. The orifice F4 suppresses the backflow of a relatively large flow rate of gas supplied by the buffer tanks T2 and T6 into the second continuous N₂ gas supply line L4.

The first flash purge line L5 extends from an N₂ gas supply source G5, which is a supply source of N₂ gas, and is connected to the first continuous N₂ gas supply line L3. Thus, the N₂ gas is supplied to the source gas supply line L1 side through the first flash purge line L5 and the first continuous N₂ gas supply line L3. The first flash purge line L5 supplies N₂ gas only when it is a purge step during film formation through an ALD method. The first flash purge line L5 is provided with a mass flow controller M5, a buffer tank T5, and an opening/closing valve V5 in this order from the side of N₂ gas supply source G5. The mass flow controller M5 controls the flow rate of the N₂ gas flowing through the first flash purge line L5. The buffer tank T5 temporarily stores the N₂ gas, and supplies the necessary N₂ gas in a short time. The opening/closing valve V5 switches the supply and stop of the N₂ gas during the purge in the ALD process.

The second flash purge line L6 extends from an N₂ gas supply source G6, which is a supply source of N₂ gas, and is connected to the second continuous N₂ gas supply line L4. Thus, the N₂ gas is supplied to the nitriding gas supply line L2 through the second flash purge line L6 and the second continuous N₂ gas supply line L4. The second flash purge line L6 supplies N₂ gas only when it is a purge step during film formation through an ALD method. The second flash purge line L6 is provided with a mass flow controller M6, a buffer tank T6, and an opening/closing valve V6 in this order from the side of the N₂ gas supply source G6. The mass flow controller M6 controls the flow rate of the N₂ gas flowing through the second flash purge line L6. The buffer tank T6 temporarily stores the N₂ gas, and supplies the necessary N₂ gas in a short time. The opening/closing valve V6 switches the supply and stop of the N₂ gas during the purge in the ALD process.

The control device 6 controls the operation of each part of the film-forming apparatus. The control device 6 includes a central processing unit (CPU), a read only memory (ROM), and a random access memory (RAM). The CPU executes a desired process according to a recipe stored in a storage region of, for example, a RAM. In the recipe, device control information for a process condition is set. The control information may be, for example, gas flow rate, pressure, temperature, and process time. A recipe and a program used by the control device 6 may be stored in, for example, a hard disk or a semiconductor memory. In addition, for example, the recipe may be set at a predetermined position to be read out in the state of being stored in a storage medium readable by a portable computer, such as a CD-ROM or a DVD.

### [Film-Forming Method]

A film-forming method according to an embodiment of the present disclosure will be described with reference to a case in which a TiN film is formed on a wafer W through an ALD process by way of an example.

First, a wafer W is loaded into the process container 1. Specifically, the gate valve 12 is opened in the state in which the substrate mounting table 2 is lowered to the transport position. Subsequently, a wafer W is loaded into the process container 1 through the loading/unloading port 11 by a transport arm (not illustrated), and is placed on the substrate mounting table 2 heated to a predetermined temperature (e.g., 350 degrees C. to 700 degrees C.) by the heater 21. Subsequently, the substrate mounting table 2 is raised to the processing position, and the inside of the process container 1 is decompressed to a predetermined degree of vacuum. Thereafter, the opening/closing valves V3 and V4 are opened, and the opening/closing valves V1, V2, V4, and V5 are closed. As a result, N₂ gas is supplied from the N₂ gas supply sources G3 and G4 to the inside of the process container 1 through the first continuous N₂ gas supply line L3 and the second continuous N₂ gas supply line L4 to raise the pressure in the process container 1 and to stabilize the temperature of the wafer W on the substrate mounting table 2. At this time, TiCl₄ gas is supplied from the source gas supply source G1 into the buffer tank T1, and thus the pressure in the buffer tank T1 is maintained substantially constant.

Subsequently, a TiN film is formed through an ALD process using TiCl₄ gas and NH₃ gas.

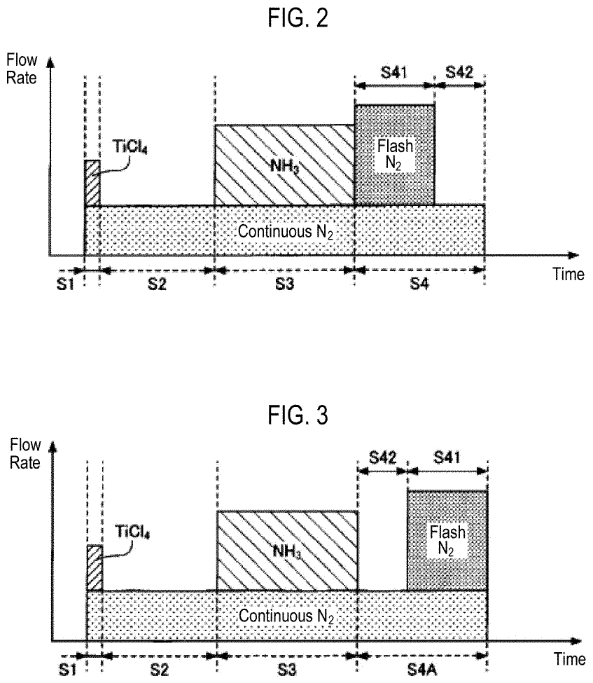

FIG. 2 is a diagram illustrating an exemplary gas supply sequence in an ALD process. The ALD process illustrated in FIG. 2 repeats a cycle including a process S1 of supplying TiCl₄ gas, a process S2 of supplying N₂ gas, a process S3 of supplying NH₃ gas, and a process S4 of supplying N₂ gas a predetermined number of times to form a TiN film having a desired film thickness on the wafer W. FIG. 2 illustrates only one cycle.

The process S1 of supplying TiCl₄ gas is a step of supplying TiCl₄ gas to the processing space 37. In the process S1 of supplying TiCl₄ gas, first, in the state in which the opening/closing valves V3 and V4 open, N₂ gas (continuous N₂ gas) is continuously supplied from the N₂ gas supply sources G3 and G4 through the first continuous N₂ gas supply line L3 and the second continuous N₂ gas supply line L4. In addition, by opening the opening/closing valve V1, TiCl₄ gas is supplied from the source gas supply source G1 through the source gas supply line L1 to the processing space 37 in the process container 1. At this time, the TiCl₄ gas is temporarily stored in the buffer tank T1 and then supplied into the process container 1. In an embodiment, in the process S1 of supplying the TiCl₄ gas, the flow rate of the TiCl₄ gas is 30 sccm to 300 sccm. In addition, the flow rate of N₂ gas supplied from each of the first continuous N₂ gas supply line L3 and the second continuous N₂ gas supply line L4 is 0.3 slm to 10 slm. In addition, the time of the process S1 of supplying TiCl₄ gas is 0.03 sec to 0.3 sec.

The S2 of supplying N₂ gas is a process of purging, for example, excess TiCl₄ gas in the processing space 37. In the process S2 of supplying N₂ gas, the supply of the TiCl₄ gas is stopped by closing the opening/closing valve V1 in the state in which the supply of the N₂ gas (continuous N₂ gas) is continued through the first continuous N₂ gas supply line L3 and the second continuous N₂ gas supply line L4. Thus, for example, the excess TiCl₄ gas in the processing space 37 is purged. In an embodiment, in the process S2 of supplying N₂ gas, the flow rates of N₂ gas supplied from each of the first continuous N₂ gas supply line L3 and the second continuous N₂ gas supply line L4 is 0.3 slm to 10 slm. In addition, the time of the process S2 of supplying N₂ gas is 0.1 sec to 0.5 sec.

The process S3 of supplying NH₃ gas is a process of supplying NH₃ gas to the processing space 37. In the process S3 of supplying NH₃ gas, the opening/closing valve V2 is opened in the state in which the supply of the N₂ gas (continuous N₂ gas) is continued through the first continuous N₂ gas supply line L3 and the second continuous N₂ gas supply line L4. Thus, the NH₃ gas is supplied to the processing space 37 from the nitriding gas supply source G2 through the nitriding gas supply line L2. At this time, the NH₃ gas is temporarily stored in the buffer tank T2 and is then supplied into the process container 1. The TiCl₄ adsorbed on the wafer W is nitrided in the process S3 of supplying NH₃ gas. At this time, the flow rate of the NH₃ gas may be set to an amount at which a nitriding reaction sufficiently occurs. In an embodiment, in the process S3 of supplying the NH₃ gas, the flow rate of the NH₃ gas is 2 slm to 10 slm. In addition, the flow rate of N₂ gas supplied from each of the first continuous N₂ gas supply line L3 and the second continuous N₂ gas supply line L4 is 0.3 slm to 10 slm. The time of the process S3 of supplying the NH₃ gas is 0.2 sec to 3 sec.

The process S4 of supplying N₂ gas is a process of purging excess NH₃ gas in the processing space 37. In the process S4 of supplying N₂ gas, a step S41 is performed, and then a step S42 is performed.

The step S41 is a step of supplying N₂ gas from the first continuous N₂ gas supply line L3 and the second continuous N₂ gas supply line L4, and supplying N₂ gas from the first flash purge line L5 and the second flash purge line L6. In the step S41, the supply of the NH₃ gas from the nitriding gas supply line L2 is stopped by closing the opening/closing valve V2 in the state in which the supply of the N₂ gas (continuous N₂ gas) is continued through the first continuous N₂ gas supply line L3 and the second continuous N₂ gas supply line L4. In addition, the opening/closing valves V5 and V6 are opened, N₂ gas (flash purge N₂ gas) is also supplied from the first flash purge line L5 and the second flash purge line L6, and excessive NH₃ gas in the processing space 37 is purged with a large flow rate of N₂ gas. At this time, the flash purge N₂ gas is temporarily stored in the buffer tanks T5 and T6 and is then supplied into the process container 1. At this time, a total flow rate of N₂ gas (flash purge) supplied from the first flash purge line L5 and the second flash purge line L6 is equal to or higher than the flow rate of TiCl₄ gas in the process S1 of supplying TiCl₄ gas. In other words, the total flow rate of the flash purge N₂ gas and the continuous N₂ gas supplied into the process container 1 in the step S41 is equal to or higher than the total flow rate of the TiCl₄ gas and the continuous N₂ gas supplied into the process container 1 in the process S1. In an embodiment, the flow rate of N₂ gas supplied from each of the first flash purge line L5 and the second flash purge line L6 is 1 slm to 5 slm. In addition, the flow rate of N₂ gas supplied from each of the first continuous N₂ gas supply line L3 and the second continuous N₂ gas supply line L4 is 0.3 slm to 10 slm. In addition, the time of the step S41 is 0.05 sec to 0.25 sec.

The step S42 is a step of supplying N₂ gas from the first continuous N₂ gas supply line L3 and the second continuous N₂ gas supply line L4, but not supplying N₂ gas from the first flash purge line L5 and the second flash purge line L6. However, the flash purge N₂ gas having a flow rate smaller than the flow rate of the flash purge N₂ gas supplied in the step S41 may be supplied in the step S42. In the step S42, the supply of the N₂ gas (continuous N₂ gas) is continued through the first continuous N₂ gas supply line L3 and the second continuous N₂ gas supply line L4. In addition, the supply of N₂ gas (flash purge N₂ gas) through the first flash purge line L5 and the second flash purge line L6 is stopped by closing the opening/closing valves V5 and V6. In an embodiment, the flow rate of N₂ gas supplied from each of the first continuous N₂ gas supply line L3 and the second continuous N₂ gas supply line L4 is 0.3 slm to 10 slm. In addition, the time of the step S42 is 0.05 sec to 0.25 sec.

Next, another exemplary gas supply sequence in an ALD process will be described. FIG. 3 is a diagram illustrating the another exemplary gas supply sequence in an ALD process. FIG. 3 illustrates only one cycle. In the ALD process illustrated in FIG. 3, a process S4A of supplying N₂ gas is performed instead of the process S4 of supplying N₂ gas after the process S3 of supplying NH₃ gas. The other processes are similar to the ALD process illustrated in FIG. 2.

In the process S4A of supplying N₂ gas, the step S42 is performed, and then the step S41 is performed. That is, in the ALD process illustrated in FIG. 3, the order of performing the steps S41 and S42 in the ALD process illustrated in FIG. 2 is reversed.

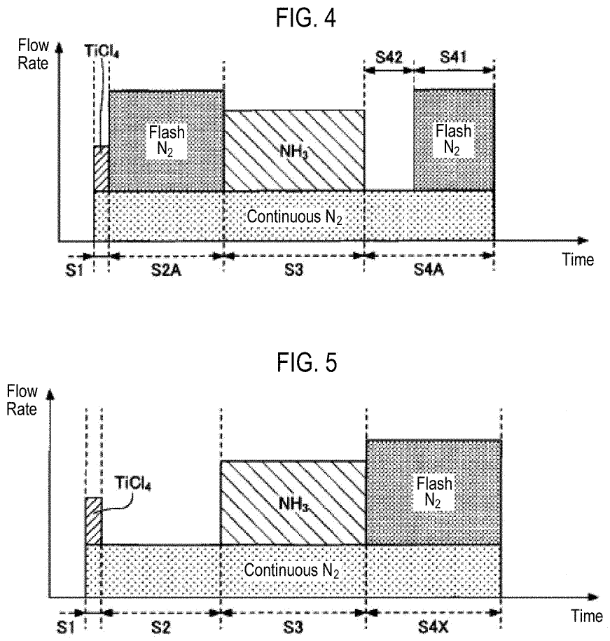

Next, still another exemplary gas supply sequence in an ALD process will be described. FIG. 4 is a diagram illustrating the still another exemplary gas supply sequence in an ALD process. FIG. 4 illustrates only one cycle. In the ALD process illustrated in FIG. 4, a process S2A of supplying N₂ gas is performed instead of the process S2 of supplying N₂ gas after the process S1 of supplying TiCl₄ gas. The other processes are similar to the ALD process illustrated in FIG. 3.

In the process S2A of supplying N₂ gas, the supply of the TiCl₄ gas from the source gas supply line L1 is stopped by closing the opening/closing valve V1 in the state in which the supply of the N₂ gas (continuous N₂ gas) is continued through the first continuous N₂ gas supply line L3 and the second continuous N₂ gas supply line L4. In addition, the opening/closing valves V5 and V6 are opened, N₂ gas (flash purge N₂ gas) is also supplied from the first flash purge line L5 and the second flash purge line L6, and excessive TiCl₄ gas in the processing space 37 is purged with a large flow rate of N₂ gas. At this time, the flash purge N₂ gas is temporarily stored in the buffer tanks T5 and T6 and is then supplied into the process container 1. At this time, the total flow rate of N₂ gas (flash purge N₂ gas) supplied from the first flash purge line L5 and the second flash purge line L6 is equal to or higher than the flow rate of TiCl₄ gas in the process S1 of supplying TiCl₄ gas. In an embodiment, the flow rate of N₂ gas supplied from each of the first flash purge line L5 and the second flash purge line L6 is 1 slm to 5 slm. In addition, the flow rate of N₂ gas supplied from each of the first continuous N₂ gas supply line L3 and the second continuous N₂ gas supply line L4 is 0.3 slm to 10 slm. In addition, the time of the process S2 of supplying N₂ gas is 0.05 sec to 0.25 sec.

### EXAMPLE

An example in which resistivity of a TiN film formed by a film-forming method according to an embodiment of the present disclosure is evaluated will be described.

### Example 1

In Example 1, a TiN film is formed on a wafer W through the ALD process shown in FIG. 2 described above. That is, after the process S3, first, the step S41 of supplying N₂ gas from the first flash purge line L5 and the second flash purge line L6 is performed. Subsequently, step S42 in which N₂ gas is not supplied from the first flash purge line L5 and the second flash purge line L6 is performed. In addition, the film thickness and the resistivity of the TiN film formed on the wafer W are measured. The process conditions of Example 1 are as follows.

Wafer temperature: 460 degrees C.
Pressure in process chamber: 3 Torr (400 Pa)
Time of one cycle: 0.85 sec
(Process S1/Process S2/Process S3/Process S4=0.05 sec/0.2 sec/0.3 sec/0.3 sec, Step S41=0.1 sec to 0.25 sec, Step S42=0.05 sec to 0.2 sec)
Flow rate of TiCl₄ gas: 50 sccm
Flow rate of NH₃ gas: 2.7 slm
N₂ gas (first continuous N₂ gas supply line L3): 3 slm
N₂ gas (second continuous N₂ gas supply line L4): 3 slm
N₂ gas (first flash purge line L5): 1 to 5 slm
N₂ gas (second flash purge line L6): 1 to 5 slm
Number of cycles: 182 times

### Example 2

In Example 2, a TiN film is formed on a wafer W through the ALD process shown in FIG. 3 described above. That is, after the process S3, first, the step S42 in which N₂ gas is not supplied from the first flash purge line L5 and the second flash purge line L6 is performed. Subsequently, the step S41 in which N₂ gas is supplied from the first flash purge line L5 and the second flash purge line L6 was performed. The process conditions of Example 2 are the same as those of Example 1 except that the order of the steps S41 and S42 is reversed. In addition, the film thickness and the resistivity of the TiN film formed on the wafer W were measured.

### Example 3

In Example 3, a TiN film is formed on a wafer W through the ALD process shown in FIG. 4 described above. That is, instead of the process S2 in Example 2, the process S2A in which N₂ gas is supplied from the first flash purge line L5 and the second flash purge line L6 is performed. The process conditions of Example 3 are the same as those of Example 2 except that after the process S1, the process S2A in which N₂ gas is supplied from the first flash purge line L5 and the second flash purge line L6 is performed. The flow rate of N₂ gas supplied from each of the first flash purge line L5 and the second flash purge line L6 in the process S2A is 1 slm to 5 slm, for example 3 slm. In addition, the film thickness and the resistivity of the TiN film formed on the wafer W are measured.

### Comparative Example 1

In Comparative Example 1, as illustrated in FIG. 5, the step of supplying N₂ gas from the first flash purge line L5 and the second flash purge line L6 (process S4x) was performed at all times in the process of supplying the N₂ gas to be performed after the process S3. In addition, the temperature of a wafer, a pressure in the process container, a time of one cycle, and flow rates of TiCl₄ gas, NH₃ gas, and N₂ gas are the same as those of Example 1. In addition, a film thickness and a resistivity of the TiN film formed on the wafer W are measured.

### Comparative Example 2

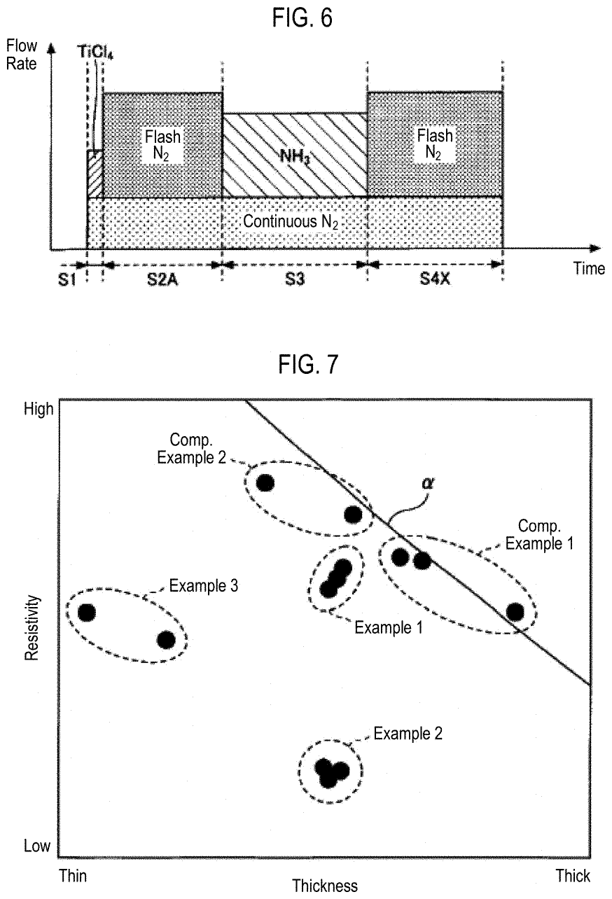

In Comparative Example 2, as illustrated in FIG. 6, N₂ gas is supplied from the first flash purge line L5 and the second flash purge line L6 at all times in the step of supplying the N₂ gas to be performed after the processes S1 and S3. That is, in Comparative Example 2, the process 4X described above is performed instead of the process 4A in Example 3. In addition, a temperature of a wafer, a pressure in the process container, a time of one cycle, and flow rates of TiCl₄ gas, NH₃ gas, and N₂ gas are the same as those of Example 1. In addition, a film thickness and a resistivity of the TiN film formed on the wafer W are measured.

### (Evaluation Result)

FIG. 7 is a diagram illustrating a relationship between the film thickness and the resistivity of a TiN film, and shows the relationship between the film thickness and the resistivity in the TiN films formed in Examples 1 to 3 and Comparative Examples 1 and 2. In FIG. 7, the horizontal axis represents the film thickness, and the vertical axis represents the resistivity. A solid line α in FIG. 7 indicates a change in resistivity when the film thickness is changed by adjusting the number of cycles in the case in which flash purge N₂ gas was not supplied in the step of supplying N₂ gas in the process of supplying N₂ gas performed after the process S1 and the process S3.

As illustrated in FIG. 7, in the case in which a TiN film has a small film thickness, the resistivity is increased when the film thickness is reduced by reducing the number of cycles (see the solid line α). It can be seen that Comparative Examples 1 and 2 have substantially the same resistivity when flash purge N2 gas was not supplied in the process of supplying N₂ gas performed after the process S1 and the process S3 (see the solid line α).

In contrast, it can be seen that the resistivity of TiN films in Examples 1 to 3 is reduced compared to the case in which the flash purge N₂ gas was not supplied in the process of supplying N₂ gas performed after the process S1 and the process S3 (see the solid line α). It can be seen that in Examples 2 and 3, the resistivity of TiN films is particularly small.

From the results of the above-described Examples 1 to 3 and Comparative Examples 1 and 2, it can be said that it is possible to form a low-resistance TiN film because the process S4 includes the step S41 and the step S42.

From the results of Examples 1 and 2, it can be said that, in the process S4, by performing the step S41 after the step S42, it is possible to form a lower-resistance TiN film.

As described above, according to an embodiment of the present disclosure, the TiN film is formed on the wafer W by repeating a cycle including the process S1 of supplying TiCl₄ gas into the process container 1 accommodating the wafer W, and the process S2 of supplying N₂ gas into the process container 1, the process S3 of supplying NH₃ gas into the process container 1, and the process S4 of supplying N₂ gas into the process container 1 a predetermined number of times. In addition, the process S4 includes the step S41 of supplying a flash purge N₂ gas having a first flow rate equal to or higher than the flow rate of the TiCl₄ gas in first process S1 and the step S42 of supplying flash purge N₂ gas having a second flow rate smaller than the first flow rate or not supplying the flash purge N₂ gas. This makes it possible to reduce a concentration of chlorine remaining in the process container 1, and to reduce the resistivity of the TiN film.

In the related art, it has been considered that when N₂ gas is supplied into the process container as much as possible after supplying a processing gas (e.g., TiCl₄ gas or NH 3 gas) into the processing container, an efficiency of replacing the processing gas with the purge gas (hereinafter, referred to as “purge efficiency”) is maximized Therefore, the flash purge N₂ gas is introduced immediately after supplying the processing gas. However, the process gas is likely to remain due to the flash purge N₂ gas, and the film-forming mode may shift from an ALD mode to a CVD mode and thus the resistivity may increase.

In the above embodiment, the process S1 is an example of the first process, the process S2 is an example of the second process, the step S3 is an example of the third process, and the step S4 is an example of the fourth process. In addition, the TiCl₄ gas is an example of the metal-containing gas, the NH₃ gas is an example of the nitriding gas, the N₂ gas is an example of the purge gas, and the TiN film is an example of the metal nitride film. Furthermore, the flash purge N₂ gas is an example of the first purge gas, and the continuous N₂ gas is an example of the second purge gas.

It shall be understood that the embodiments disclosed herein are examples in all respects and are not restrictive. The above-described embodiments may be omitted, replaced, or modified in various forms without departing from the scope and spirit of the appended claims.

TiCl₄ gas has been exemplified as the metal-containing gas in the embodiment described above, but is not limited thereto. Various metal-containing gases may be used. For example, a TiN film may be formed using TaCl₄ gas as the metal-containing gas. In addition, NH₃ gas has been exemplified as the nitriding gas, but is not limited thereto. For example, various nitriding gases, such as N₂H₄, may be used.

In the embodiment described above, a case in which a TiN film is formed as an example of the metal nitride film has been described. However, the present disclosure is not limited thereto. For example, the above-described film-forming method may also be applied when forming a TaN film or a TiSiN film. When forming a TiSiN film, for example, a process of alternately repeating supply of a Ti-containing gas and supply of a nitriding gas with a purge interposed therebetween, and a process of alternately repeating supply of a Si-containing gas and supply of a nitriding gas with the purge interposed therebetween may be performed a predetermined number of times. In this case, the above-described film forming method may be applied to the process of alternately repeating the supply of the Ti-containing gas and the supply of the nitriding gas with the purge interposed therebetween.

According to the present disclosure, it is possible to form a low-resistance metal nitride film.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film-forming method for forming a metal nitride film on a substrate, the method comprising:
forming the metal nitride film on the substrate by repeating a cycle a predetermined number of times, the cycle including:
a first process of supplying a metal-containing gas into a process container configured to accommodate the substrate therein;
a second process of supplying a purge gas into the process container;
a third process of supplying a nitrogen-containing gas into the process container; and
a fourth process of supplying the purge gas into the process container,
wherein the fourth process includes:
a first step of supplying a first purge gas having a first flow rate equal to or larger than a flow rate of the metal-containing gas of the first process; and
a second step of supplying the first purge gas having a second flow rate smaller than the first flow rate.

2. The film-forming method of claim 1, wherein in the second step, the first purge gas is not supplied.

3. The film-forming method of claim 1, wherein, in the fourth process, the first step is performed after the second step.

4. The film-forming method of claim 1, wherein, in the fourth process, the second step is performed after the first step.

5. The film-forming method of claim 1, wherein, in all of the first process to the fourth process, a second purge gas is constantly supplied into the process container.

6. The film-forming method of claim 5, wherein the first purge gas and the second purge gas are supplied from different gas supply lines, respectively.

7. The film-forming method of claim 5, wherein, in the second process, the first purge gas having a third flow rate is supplied, the third flow rate being equal to or larger than the flow rate of the metal-containing gas of the first process.

8. The film-forming method of claim 5, wherein, in the second process, the first purge gas is not supplied.

9. The film-forming method of claim 1, wherein the metal-containing gas is TiCl₄ gas, and the nitrogen-containing gas is NH₃ gas.

10. The film-forming method of claim 1, wherein the metal nitride film is a TiN film.

11. A film-forming apparatus comprising:
a process container configured to accommodate a substrate therein;
a processing gas supply mechanism configured to supply a metal-containing gas, a nitrogen-containing gas, and a purge gas into the process container; and
a controller configured to control the processing gas supply mechanism,
wherein the controller is configured to perform a process including:
repeating a cycle a predetermined number of times, the cycle including: a first process of supplying the metal-containing gas into the process container, a second process of supplying the purge gas into the process container, a third process of supplying the nitrogen-containing gas into the process container, and a fourth process of supplying the purge gas into the process container; and
performing, in the fourth process, a first step of supplying a first purge gas having a first flow rate equal to or larger than a flow rate of the metal-containing gas of the first process, and a second step of supplying the first purge gas having a second flow rate smaller than the first flow rate.

12. The film-forming apparatus of claim 11, wherein in the second step, the first purge gas is not supplied.
